(19) United States
(12) Patent Application Publication
(10) Pub. No.: US 2002/0024139 A1
(43) Pub. Date: Feb. 28, 2002

(54) Combined capping layer and ARC for CU interconnects

(76) Inventors: Simon S. Chan, Saratoga, CA (US); John Iacoponi, Austin, TX (US)

Correspondence Address: MCDERMOTT WILL & EMERY, 600 13TH STREET, N.W., WASHINGTON, DC, 20005-3096, US

(21) Appl. No.: 09/498,334

(22) Filed: Feb. 4, 2000

(51) Int. Cl. H01L 29/40; H01L 23/52; H01L 23/48

(52) U.S. Cl. 257/758

(57) ABSTRACT

Cu interconnects are provided with a combined capping layer and ARC. The capping layer prevents Cu diffusion while the ARC minimizes reflectivity thereby enhancing the accuracy of subsequent photolithography. Embodiments include filling a damascene opening with Cu or a Cu alloy, planarizing, depositing a silicon nitride capping layer and then depositing a silicon oxynitride ARC on the silicon nitride capping layer.

### TECHNICAL FIELD

The present invention relates semiconductor devices comprising copper (Cu) or Cu alloy interconnection patterns. The present invention is applicable to manufacturing high speed integrated circuits having submicron design features and high conductivity interconnect structures.

### BACKGROUND ART

The escalating requirements for high density and performance associated with ultra large scale integration semiconductor wiring require responsive changes in interconnection technology. Such escalating requirements have been found difficult to satisfy in terms of providing a low RC (resistance capacitance) interconnection pattern, particularly wherein submicron vias, contacts and conductive lines have high aspect ratios due to miniaturization.

Conventional semiconductor devices typically comprise a semiconductor substrate, normally of doped monocrystalline silicon, and a plurality of sequentially formed dielectric interlayers and conductive patterns. An integrated circuit is formed containing a plurality of conductive patterns comprising conductive lines separated by interwiring spacings, and a plurality of interconnect lines, such as bus lines, bit lines, word lines and logic interconnect lines. Typically, the conductive patterns on different layers, i.e., upper and lower layers, are electrically connected by a conductive plug filling a via opening, while a conductive plug filling a contact opening establishes electrical contact with an active region on a semiconductor substrate, such as a source/drain region. Conductive lines formed in trenches which typically extend substantially horizontal with respect to the semiconductor substrate. Semiconductor “chips” comprising five or more levels of metallization are becoming more prevalent as device geometries shrink to submicron levels.

A conductive plug filling a via opening is typically formed by depositing a dielectric interlayer on a conductive layer comprising at least one conductive pattern, forming an opening in the dielectric interlayer by conventional photolithographic and etching techniques, and filling the opening with a conductive material, such as tungsten (W). Excess conductive material on the surface of the dielectric interlayer can be removed by chemical-mechanical polishing (CMP). One such method is known as damascene and basically involves the formation of an opening which is filled in with a metal. Dual damascene techniques involve the formation of an opening comprising a lower contact or via opening section in communication with an upper trench opening section, which opening is filled with a conductive material, typically a metal, to simultaneously form a conductive plug in electrical contact with a conductive line.

High performance microprocessor applications require rapid speed of semiconductor circuitry. The control speed of semiconductor circuitry varies inversely with the resistance and capacitance of interconnection pattern. As integrated circuits become more complex and feature sizes and spacings become smaller, the integrated circuit speed becomes less dependent upon the transistor itself and more dependent upon the interconnection pattern. Miniaturization demands long interconnects having small contacts and small cross-sections. Thus, the interconnection pattern limits the speed of the integrated circuit. If the interconnection node is routed over a considerable distance, e.g., hundreds of microns or more, as in submicron technologies, the interconnection capacitance limits the circuit node capacitance loading and, hence, the circuit speed. As integration density increases and feature size decreases in accordance with submicron design rules, e.g., a design rule of about 0.18 μn and below, the rejection rate due to integrated circuit speed delays severely limits production throughput and significantly increases manufacturing costs.

Cu and Cu alloys have received considerable attention as a replacement material for Al in VLSI interconnection metalizations. Cu has a lower resistivity than Al, and has improved electrical properties vis-À-vis W, making Cu a desirable metal for use as a conductive plug as well as metal wiring.

An approach to forming Cu plugs and wiring comprises the use of damascene structures employing CMP, as in Chow et al., U.S. Pat. No. 4,789,648. However, due to Cu diffusion through the dielectric interlayer, Cu interconnect structures must be encapsulated by a diffusion barrier layer. Typical diffusion barrier metals include tantalum (Ta), tantalum nitride (TaN), titanium (Ti), titanium nitride (TiN), titanium tungsten (TiW), and silicon nitride (Si₃N₄) for encapsulating Cu. The use of such barrier materials to encapsulate Cu is not limited to the interface between Cu and the dielectric interlayer, but includes interfaces with other metals as well.

There are, however, significant problems attendant upon conventional Cu interconnect methodology employing a diffusion barrier layer. For example, conventional practices comprise forming a damascene opening in a dielectric interlayer, depositing a barrier layer such as TaN, filling the opening with Cu or a Cu alloy layer, CMP, and forming a capping layer on the exposed surface of the Cu or Cu alloy. It was found, however, that capping layers, such as silicon nitride, exhibit poor antireflective properties, thereby limiting the resolution of subsequent photolithographic techniques in forming an opening in a dielectric layer formed thereon for the next metallizaton level. As design rules extend deeper into the submicron range, e.g., about 0.18 microns and under, the reliability of the interconnect pattern becomes particularly critical. Accordingly, the accuracy of photolithographic techniques in patterning the interconnection structure becomes even more critical.

There exists a need for methodology enabling the formation of encapsulated Cu and Cu alloy interconnect members having high reliability while enabling subsequent level photolithographic processing with greater accuracy.

### DISCLOSURE OF THE INVENTION

An advantage of the present invention is a semiconductor device having highly reliable Cu or Cu alloy interconnect members.

Another advantage of the present invention is a method of manufacturing a semiconductor device comprising a highly reliable Cu or Cu alloy interconnect member.

Additional advantages and other features of the present invention will be set forth in the description which follows and in part will be apparent to those having ordinary skill in the art upon examination of the following or may be learned from the practice of the present invention. The advantages of the present invention may be realized and obtained as particularly pointed out in the appended claims.

According to the present invention, the foregoing and other advantages are achieved in part by a semiconductor device comprising: a layer of copper (Cu) or a Cu alloy; a layer of silicon nitride on the Cu or Cu alloy layer; and a layer of silicon oxynitride on the silicon nitride layer.

Another aspect of the present invention is a method of manufacturing a semiconductor device, the method comprising: forming a layer of copper (Cu) or a Cu alloy; forming a layer of silicon nitride on the Cu or Cu alloy layer; and forming a layer of silicon oxynitride on the silicon nitride layer.

Embodiments include forming a damascene opening in a first dielectric layer, depositing a barrier layer in the opening and on the first dielectric layer, filling the opening with Cu or a Cu alloy, planarizing, depositing a silicon nitride layer on an exposed surface of the Cu or Cu alloy layer in the first opening and on the first dielectric layer, and depositing the silicon oxynitride layer on the silicon nitride layer. Embodiments also include depositing a second dielectric layer, forming an opening therethrough in communication with the underlying Cu or Cu alloy, and filing the opening in the second dielectric layer with Cu or a Cu alloy.

Additional advantages of the present invention will become readily apparent to those skilled in this art from the following detailed description, wherein embodiments of the present invention are described, simply by way of illustration of the best mode contemplated for carrying out the present invention. As will be realized, the present invention is capable of other and different embodiments, and its several details are capable of modifications in various obvious respects, all without departing from the present invention. Accordingly, the drawings and description are to be regarded as illustrative in nature, and not as restrictive.

### BRIEF DESCRIPTION OF DRAWINGS

FIGS. 1-3 schematically illustrate sequential phases of a method in accordance with an embodiment of the present invention.

### DESCRIPTION OF THE INVENTION

The present invention addresses and solves problems attendant upon capping a Cu or Cu alloy interconnect member, as with a silicon nitride capping layer, while minimizing reflectivity thereby enabling highly accurate photolithographic resolution in patterning a dielectric layer formed on the Cu or Cu alloy interconnect. Accordingly, the present invention enables effective and efficient use of Cu or Cu alloy metalization in forming reliable Cu or Cu alloy interconnection patterns employing damascene technology in manufacturing submicron semiconductor devices, e.g., semiconductor devices having a design rule of about 0.18 and under. As employed throughout this application, the symbol Cu is intended to encompass high purity elemental copper as well as Cu-based alloys, such as Cu alloys containing minor amounts of tin, zinc, manganese, titanium and germanium.

As design rules are scaled down into the deep submicron range, e.g., about 0.18 microns and under, the reliability of encapsulated Cu and/or Cu alloy interconnect members becomes increasingly significant. Conventional practices comprise forming a silicon nitride capping layer on Cu metalization subsequent to planarization by CMP. Silicon nitride does not interact with Cu metalization and serves as a suitable diffusion barrier. However, silicon nitride does not exhibit the requisite antireflective properties to minimize reflectivity during subsequent photolithographic processing, as in forming an opening in a dielectric layer deposited on the capping layer.

The present invention constitutes an improvement over such conventional capping layer practices by forming a composite capping layer which comprises an initial layer of silicon nitride as it does not interact with the underlying Cu metalization and serves as a suitable diffusion barrier. However, in accordance with the present invention, a layer of silicon oxynitride is deposited on the silicon nitride layer. Silicon oxynitride also functions as a suitable diffusion barrier; however, it exhibits a suitable reflectivity to function as an effective antireflective coating (ARC). Advantageously, the initial layer of silicon nitride prevents interaction between the silicon oxynitride and underlying Cu metalization thereby avoiding Cu oxidation. Thus, the composite capping layer of the present invention exhibits optimal barrier and antireflective properties.

Embodiments of the present invention include depositing the initial silicon nitride layer at a thickness of about 500 Å to about 1,000 Å, and depositing the silicon oxynitride layer at a thickness of about 300 Å to about 400 Å. The composite silicon nitride/silicon oxynitride capping layer of the present invention advantageously prevents Cu diffusion and simultaneously functions as a bottom ARC for subsequent photolithographic processing on an overlying dielectric layer.

Advantageously, both the silicon nitride layer and silicon oxynitride layer can be deposited in a single deposition chamber by plasma enhanced chemical vapor deposition (PECVD) by simply altering the deposition chemistry. For example, after depositing the initial silicon nitride layer, an oxygen-containing gas, such as nitrous oxide, can be admitted into the deposition chamber.

Cu and/or Cu alloy interconnect members formed in accordance with embodiments of the present invention can be, but are not limited to, interconnects formed by damascene technology. Thus, embodiments of the present invention include forming an interdielectric layer overlying a substrate, forming an opening, e.g., a damascene opening, in the interdielectric layer, depositing a diffusion barrier layer, such as Ta or TaN lining the opening and on the interdielectric layer, and filling the (opening with Cu or a Cu alloy layer. Advantageously, the opening in the dielectric interlayer can be filled with Cu or a Cu alloy by physical vapor deposition (PVD), CVD, electroless plating or electroplating. A conventional seed layer is initially deposited when electroplating or electroless plating the Cu or Cu alloy layer. CMP is then performed such that the upper surface of the Cu or Cu alloy layer is substantially coplanar with the upper surface of the interdielectric layer. The wafer is then placed in a conventional PECVD chamber and the initial layer of silicon nitride is deposited, as to a thickness between about 500 Å to about 1,000 Å, employing conventional chemistry, e.g., silicon and nitrogen containing gases, such as, silane and ammonia or silane and nitrogen in a plasma assisted process at a temperature up to 400° C. After the silicon nitride layer has been deposited, the deposition chemistry is altered, as by introducing an oxygen-containing gas, to form a layer of silicon oxynitride directly on the layer of silicon nitride, thereby forming the composite capping layer/ARC of the present invention.

In various embodiments of the present invention, conventional substrates, interdielectric layers, and barrier layers can be employed. For example, the substrate can be doped monocrystalline silicon or gallium-arsenide. The interdielectric layer employed in the present invention can comprise any dielectric material conventionally employed in the manufacture of semiconductor devices. For example, dielectric materials such as silicon dioxide, phospho-silicate-glass (PSG), boron doped PSG (BPSG), and silicon dioxide derived from tetraethylorthosilicate (TEOS) or silane by PECVD or F-doped SiO₂ can be employed. Interdielectric layers in accordance with the present invention can also comprise low dielectric constant materials, including polymers, such as polyamides. The opening formed in dielectric layers are effected by conventional photolithographic and etching techniques.

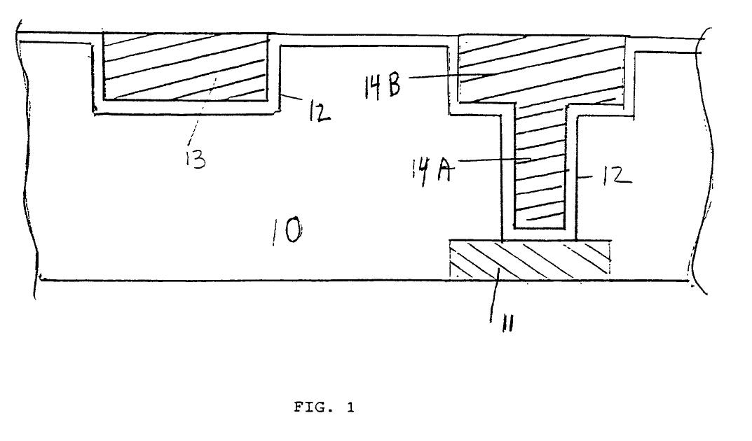

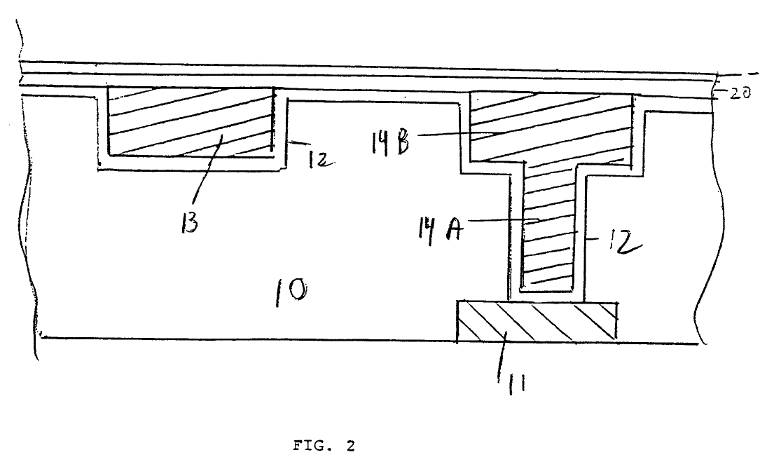

An embodiment of the present invention is schematically illustrated in FIGS. 1-3, wherein similar reference numerals denote similar features. Adverting to FIG. 1, a single damascene trench opening and a dual damascene trench opening are formed in dielectric layer 10. The dual damascene opening communicates with an underlying conductive feature 11. A barrier layer 12 is deposited, as by PVD or CVD, lining the damascene openings and on the upper surface of dielectric layer 10. Cu or a Cu alloy is then deposited on the barrier layer 12 filling the damascene openings. The Cu metalization filling the single damascene trench opening is designated by reference numeral 13 and forms a metal line. Cu metalization filling the dual damascene opening is designated by reference numerals 14A, 14B wherein 14A constitutes a via and reference numeral 14B denotes a metal line in electrical communication with via 14A. Subsequent to Cu metalization, CMP is performed resulting in the structure depicted in FIG. 1. The wafer is then placed in a conventional PECVD chamber and a layer of silicon nitride 20 is deposited on the planarized surface, as shown in FIG. 2. When the layer of silicon nitride 20 achieves a desired thickness, e.g. between about 500 Å to about 1,000 Å, the deposition chemistry is altered, as by admitting an oxygen-containing gas, such as nitrous oxide, to deposit a layer of silicon oxynitride 21 having suitable antireflective properties, thereby minimizing reflection and enhancing the accuracy of subsequent photolithographic processing.

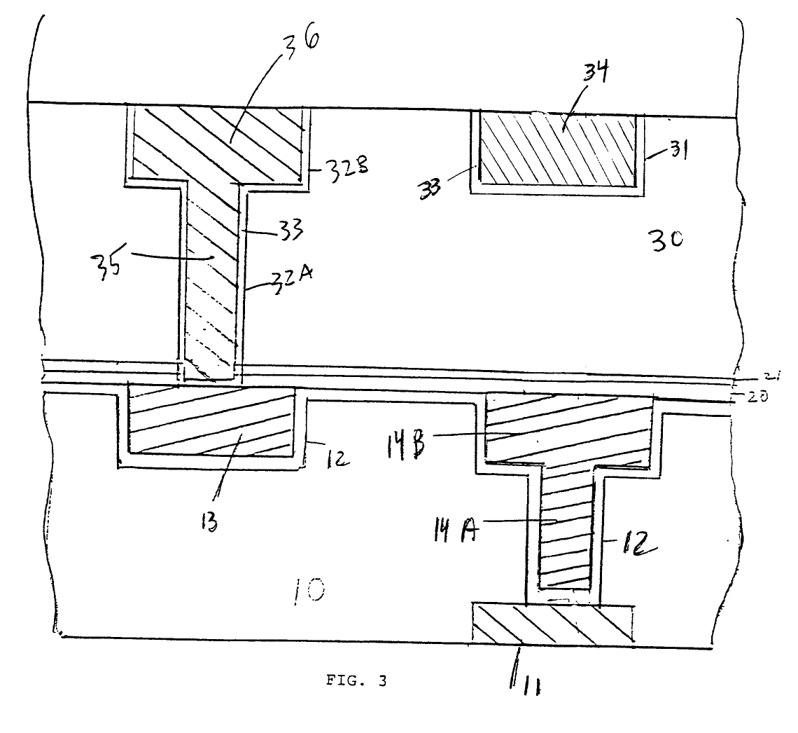

As shown in FIG. 3, a second dielectric layer 30 is deposited, a photomask (not shown) is formed thereon, photolithographic and etch processing is conducted to form single damascene opening 31 and dual damascene opening 32A, 32B. A barrier layer 33 is then deposited to line the damascene openings and Cu or a Cu alloy is deposited to fill the openings. Planarization is then conducted. The Cu metalization forms conductive line 34 and a composite of conductive via 35 in communication with metal line 36. The use of a composite capping layer comprising an outer ARC 21 of silicon oxynitride enables the accurate formation for damascene openings 31 and 32A, 32B, during subsequent photolithographic processing in patterning the overlying dielectric layer 30. Additional metallization levels can be vertically applied.

The present invention enables the formation of extremely reliable Cu and/or Cu alloy interconnect members by forming a composite capping layer of silicon nitride and silicon oxynitride thereon. Both silicon nitride and silicon oxynitride prevent Cu diffusion, while the silicon oxynitride functions as a bottom ARC during subsequent photolithographic processing. The present invention enjoys industrial applicability in forming various types of inlaid Cu and Cu alloy interconnection patterns. The present invention is particularly applicable in manufacturing semiconductor devices having submicron features and high aspect ratio openings, e.g. semiconductor devices with a design rule of about 0.18 microns and under.

In the previous description, numerous specific details are set forth, such as specific materials, structures, chemicals, processes, etc., to provide a better understanding of the present invention. However, the present invention can be practiced without resorting to the details specifically set forth. In other instances, well known processing and materials have not been described in detail in order not to unnecessarily obscure the present invention.

Only the preferred embodiment of the present invention and but a few examples of its versatility are shown and described in the present disclosure. It is to be understood that the present invention is capable of use in various other combinations and environments and is capable of changes or modifications within the scope of the inventive concept as expressed herein.

What is claimed is:

1. A semiconductor device comprising:
a layer of copper (Cu) or a Cu alloy;
a layer of silicon nitride on the Cu or Cu alloy layer; and
a layer of silicon oxynitride on the silicon nitride layer.

2. The semiconductor device according to claim 1, wherein;
the silicon nitride layer has a thickness of about 500 Å to about 1,000 Å; and
the silicon oxynitride layer has a thickness of about 300 Å to about 400 Å.

3. The semiconductor device according to claim 1, comprising:
a first dielectric layer;
a first opening in the first dielectric layer; the Cu or Cu alloy substantially filling the first opening and having an exposed upper surface;
the silicon nitride layer on the exposed upper surface and on the first dielectric layer; and
the silicon oxynitride layer on the silicon nitride layer.

4. The semiconductor device according to claim 3, further comprising:
a barrier layer lining the first opening; and
the Cu or Cu alloy layer on the barrier layer.

5. The semiconductor device according to claim 3, further comprising:
a second dielectric layer on the silicon oxynitride layer;
a second opening which may or may not extend through the second dielectric layer, silicon oxynitride layer and silicon nitride layer; and
a conductive material filling the second opening.

6. The semiconductor device according to claim 5, comprising:
a barrier layer lining the second opening; and
Cu or a Cu alloy layer on the barrier layer substantially filling the second opening.

7. The semiconductor device according to claim 5, wherein;
the second opening constitutes a single damascene opening comprising a trench or a dual damascene opening comprising a via hole in communication with a trench; and
the Cu or Cu alloy filling the second opening forms a metal line or a composite of a metal connected to a via, respectively.

8. The semiconductor device according to claim 3, wherein the first opening is a trench and the Cu or Cu alloy filling the first opening forms a metal line.

9. A method of manufacturing a semiconductor device, the method comprising:
forming a layer of copper (Cu) or a Cu alloy;
forming a layer of silicon nitride on the Cu or Cu alloy layer; and
forming a layer of silicon oxynitride on the silicon nitride layer.

10. The method according to claim 9, comprising:
depositing the silicon nitride layer to a thickness of about 500 Å to about 1,000 Å; and
depositing the silicon oxynitride layer to a thickness of about 300 Å to about 400 Å.

11. The method according to claim 9, comprising:
depositing a first dielectric layer;
forming a first opening in the first dielectric layer;
depositing the Cu or Cu alloy layer in the first opening and on the first dielectric layer;
planarizing leaving an upper surface of the Cu or Cu alloy layer exposed;
depositing the silicon nitride on the exposed surface of the Cu or Cu alloy layer and on the first dielectric layer; and
depositing the layer of silicon oxynitride on the silicon nitride layer.

12. The method according to claim 11, comprising:
depositing a barrier layer lining the first opening; and
depositing the Cu or Cu alloy layer on the barrier layer.

13. The method according to claim 11, comprising planarizing by chemical mechanical polishing.

14. The method according to claim 11, comprising:
forming a second dielectric layer on the first dielectric layer;
forming a photomask on the second dielectric layer;
using the photomask, etching to form a second opening through the second dielectric layer, silicon oxynitride layer and silicon nitride layer;
removing the photomask; and
filling the second opening with a conductive material.

15. The method according to claim 14, comprising:
depositing a barrier layer lining the second opening; and
depositing a Cu or Cu alloy on the barrier layer.

16. The method according to claim 14, wherein the second opening constitutes a single damascene opening comprising a trench or a dual damascene opening comprising a via hole communicating with a trench, and the conductive material filling the second opening constitutes a metal line or a composite of a metal line connected to a via, respectively.

17. The method according to claim 11, wherein the first opening comprises a single damascene opening comprising a trench or a dual damascene opening comprising a via hole in communication with a trench, and the Cu or Cu alloy layer filling the first opening constitutes a metal line or a composite of a via in communication with a metal line, respectively.

18. The method according to claim 9, comprising depositing the silicon nitride layer and silicon oxynitride layer in the same deposition chamber.

19. The method according to claim 18, comprising:
depositing the silicon nitride layer by plasma enhanced chemical vapor deposition in a chamber containing reactive gases; and
altering the composition of the reactive gasses in the deposition chamber to deposit a layer of silicon oxynitride on the silicon nitride layer.
